(19) United States
(12) Patent Application Publication
(10) Pub. No.: US 2026/0240053 A1
(43) Pub. Date: Aug. 13, 2026

(54) DIE STACK WITH THROUGH SUBSTRATE VIAS

(71) Applicant: Skyworks Solutions, Inc., Irvine, CA (US)

(72) Inventors: Reza Kasnavi, Solana Beach, CA (US); Sundeep Nand Nangalia, Raleigh, NC (US)

(21) Appl. No.: 19/537,355

(22) Filed: Feb. 11, 2026

Related U.S. Application Data
(60) Provisional application No. 63/757,436, filed on Feb. 12, 2025.

(51) Int. Cl. H10W 90/00

(52) U.S. Cl. CPC H10W 90/754; H10W 90/00; H10W 90/752

(57) ABSTRACT

A stacked die package comprising: a first semiconductor die including a front side, a back side that is opposite to the front side, and one or more through substrate vias within the first semiconductor die vertically connecting the front side and the back side of the first semiconductor die; a second semiconductor die including a front side and a back side that is opposite to the front side; and a bonding structure between the back side of the first semiconductor die and the front side of the second semiconductor die and configured to create a connection path from the front side of the second semiconductor die to the one or more through substrate vias of the first semiconductor die at the back side of the first semiconductor die.

### CROSS-REFERENCE TO RELATED APPLICATIONS

Any and all applications for which a foreign or domestic priority claim is identified in the Application Data Sheet as filed with the present application are hereby incorporated by reference under 37 CFR 1.57.

### BACKGROUND

Field

Embodiments of the invention relate to a stacked die package through a plurality of through substrate vias (TSVs).

### Description of the Related Technology

Packaging integration refers to the integration of separately manufactured components into a higher-level assembly that provides enhanced functionality and improved operating characteristics. Stacked die packaging is a technique that involves stacking multiple dies on top of each other and bonding them together in a single package. Stacked die packaging has many advantages over traditional single-die packages, such as improved space efficiency, improved performance and lower power consumption.

Stacked die packaging was originally developed to double the memory density of devices by placing two memory chips in a single package. Today, the technology is used to combine different technologies into the same package, such as flash memories with application-specific integrated circuits (ASICs).

### SUMMARY

According to a first aspect there is provided a stacked die package comprising: a first semiconductor die including a front side, a back side that is opposite to the front side, and one or more through substrate vias within the first semiconductor die vertically connecting the front side and the back side of the first semiconductor die; a second semiconductor die including a front side and a back side that is opposite to the front side; and a bonding structure between the back side of the first semiconductor die and the front side of the second semiconductor die and configured to create a connection path from the front side of the second semiconductor die to the one or more through substrate vias of the first semiconductor die at the back side of the first semiconductor die.

In one example, the front side of the first die includes a first active electronic device.

In one example, the front side of the second die includes a second active electronic device.

In one example, the bonding structure is configured to couple the first active electronic device of the first die and the second active electronic device of the second die.

In one example, the bonding structure includes one or more interconnect members connected to the one or more through substrate vias.

In one example, the one or more interconnect members include micro copper pillars.

In one example, the one or more interconnect members include a redistribution layer coupled to the micro copper pillars.

In one example, the one or more interconnect members include landing pads each connected between the redistribution layer and the one or more through substrate vias.

In one example, the front side of the first die is connected to a printed circuit board through one or more bonding elements.

In one example, the one or more bonding elements include a plurality of micro copper pillars.

In one example, the one or more bonding elements further include metal pads configured to connect the micro copper pillars to the printed circuit board.

In one example, the first die is a flip-chip die.

In one example, the second die is a flip-chip die.

According to a second aspect there is provided a multiple stacked dies assembly comprising: a plurality of semiconductor dies connected to each other back-to-front in a vertical stack through a bonding structure between each two adjacent semiconductor dies, wherein each semiconductor die includes: a front side, a back side that is opposite to the front side, and one or more through substrate vias within the semiconductor die vertically connecting the front side and the back side and a back side that is opposite to the front side; and wherein the bonding structure is configured to create a connection path between two adjacent semiconductor dies to the one or more through substrate vias of each semiconductor die of the plurality of semiconductor dies.

According a third aspect there is provided, a method of manufacturing a stacked die package, the method comprising: forming copper pillar bumps on a silicon wafer, the silicon wafer including a front side, a back side that is opposite to the front side, and one or more through substrate vias within the silicon wafer vertically connecting the front side and the back side of the silicon wafer; grinding and polishing the back side of the silicon wafer to reveal the one or more through substrate vias at the back side; fabricating one or more connection components at the back side of the silicon wafer; dicing the silicon wafer to divide into a plurality of first dies, each first die including a front side, a back side that is opposite to the front side, and one or more through substrate vias within the first die; and coupling a second die to the first die through connecting one or more micro copper pillars on a front side of the second die to the one or more connection components at the back side of the first die.

In one example, the one or more connection components include a redistribution layer.

In one example, the one or more connection components include one or more landing pads.

In one example, the front side of the first die includes a first active electronic device.

In one example, the front side of the second die includes a second active electronic device.

In one example, the method further comprises coupling the front side of the second die to the back side of the first die through the redistribution layer.

In one example, the redistribution layer is connected between the one or more micro copper pillars on the front side of the second die and the landing pads.

In one example, the method further comprises directly coupling the front side of the second die to the back side of the first die at the one or more landing pads.

In one example, the method further comprises connecting the first die to a printed circuit board through the copper pillars at the front side of the first die.

In one example, the first die is a flip-chip die.

In one example, the second die is a flip-chip die.

Still other aspects, embodiments, and advantages of these exemplary aspects and embodiments are discussed in detail below. Embodiments disclosed herein may be combined with other embodiments in any manner consistent with at least one of the principles disclosed herein, and references to “an embodiment,” “some embodiments,” “an alternate embodiment,” “various embodiments,” “one embodiment” or the like are not necessarily mutually exclusive and are intended to indicate that a particular feature, structure, or characteristic described may be included in at least one embodiment. The appearances of such terms herein are not necessarily all referring to the same embodiment.

### BRIEF DESCRIPTION OF THE DRAWINGS

Various aspects of at least one embodiment are discussed below with reference to the accompanying figures, which are not intended to be drawn to scale. The figures are included to provide illustration and a further understanding of the various aspects and embodiments, and are incorporated in and constitute a part of this specification, but are not intended as a definition of the limits of the invention. In the figures, each identical or nearly identical component that is illustrated in various figures is represented by a like numeral. For purposes of clarity, not every component may be labeled in every figure. In the figures:

FIG. 1 is a schematic diagram of a stacked die package 100 including a silicon interposer;

FIG. 2 is a schematic diagram of a stacked die package 200 including a plurality of TSVs and a redistribution layer (RDL) for routing flexibility, according to the present disclosure;

FIG. 3 is a schematic diagram of a stacked die package 300 including a plurality of TSVs and metal pads, according to the present disclosure;

FIG. 4 is a flowchart showing a set of method steps in a process of manufacturing the first die of the stacked die package 200 of FIG. 2 according to the present disclosure;

FIG. 5 is a flowchart showing a set of method steps in a process of manufacturing the first die of the stacked die package 300 of FIG. 3 according to the present disclosure; and

FIG. 6 is a flowchart showing a set of method steps in a process of assembling the stacked die package on a printed circuit board according to the present disclosure.

### DETAILED DESCRIPTION

It is to be appreciated that embodiments of the methods and apparatuses discussed herein are not limited in application to the details of construction and the arrangement of components set forth in the following description or illustrated in the accompanying drawings. The methods and apparatuses are capable of implementation in other embodiments and of being practiced or of being carried out in various ways. Examples of specific implementations are provided herein for illustrative purposes only and are not intended to be limiting. Also, the phraseology and terminology used herein is for the purpose of description and should not be regarded as limiting. The use herein of “including,” “comprising,” “having,” “containing,” “involving,” and variations thereof is meant to encompass the items listed thereafter and equivalents thereof as well as additional items. References to “or” may be construed as inclusive so that any terms described using “or” may indicate any of a single, more than one, and all of the described terms.

Some methods for die stacking include using a silicon interposer and flip-chip assembly. When using a silicon interposer, a thin piece of silicon is applied in between dies to connect the dies. The dies can be bonded to the interposer using solder bonding, adhesive bonding, or stud bonding. In a flip-chip assembly, the dies are bonded directly to the printed circuit board (PCB) pads. This method is more complex than the silicon interposer but provides better electrical performance.

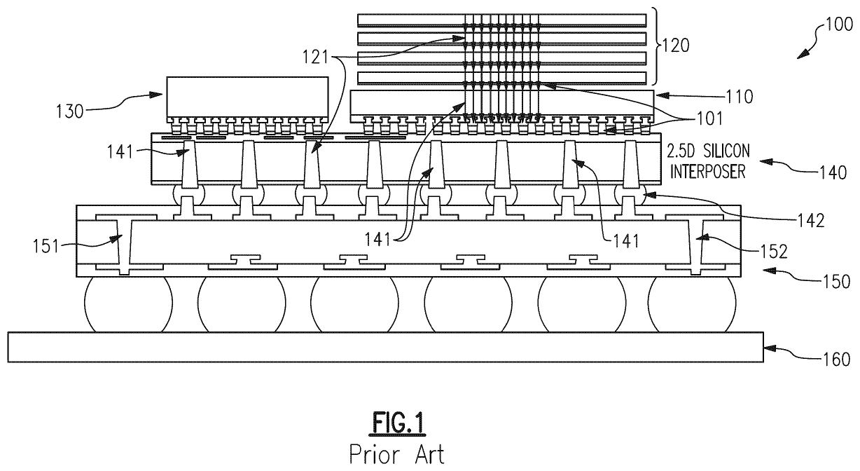

A stacked die package 100 is shown in FIG. 1. The stacked die package 100 includes a logic die 110, a plurality of memory dies 120, and a processing unit 130. The plurality of memory dies 120 form a die stack. Each layer of memory die includes TSVs and the layers are connected to each other vertically using these TSVs 121. Such an interconnected stack of memory dies is then bonded on top of the logic die 110 through bonding assembly 101 (e.g. chip-to-wafer, or wafer-to-wafer bonding assembly). The processing unit 130 and the logic die 110 are then bonded on a 2.5 D silicon interposer 140 in a side-by-side arrangement through bonding assembly, as shown in FIG. 1. The 2.5D silicon interposer 140 includes a plurality of TSVs 141 formed within the interposer 140 and a plurality of Control Collapse Chip Connection (C4) bumps to connect the silicon interposer 140 to a ball grid array (BGA) laminate 150. The substrate of BGA laminate 150 includes two TSVs 151 and 152 patterned at two ends of the substrate. The BGA laminate 150 then connects the 2.5D silicon interposer 140 to a PCB 160.

Such a stacked die package uses a silicon interposer 140 to connect the active components (e.g. the logic die, memory dies and the processing unit) to the PCB substrate which has to build up the depth in the Y direction of the whole package. Also, the logic die 110 and the processing unit 130 are arranged side-by-side which also increases the width in the X direction of the whole package.

Therefore, a reduction in the size of the package in the width (or X direction) and depth (or Y direction) is desired. Enhancing functionality while reducing the X-Y footprint of modules is approaching technological boundaries. One method to boost performance without expanding the current module footprint is to adopt vertical integration by stacking dies, without using an interposer, taking advantages of the use of TSVs.

The present disclosure relates to a stacked die package comprising: a first semiconductor die including a front side, a back side that is opposite to the front side, and one or more through substrate vias within the first semiconductor die vertically connecting the front side and the back side of the first semiconductor die; a second semiconductor die including a front side and a back side that is opposite to the front side; and a bonding structure between the back side of the first semiconductor die and the front side of the second semiconductor die and configured to create a connection path from the front side of the second semiconductor die to the one or more through substrate vias of the first semiconductor die at the back side of the first semiconductor die.

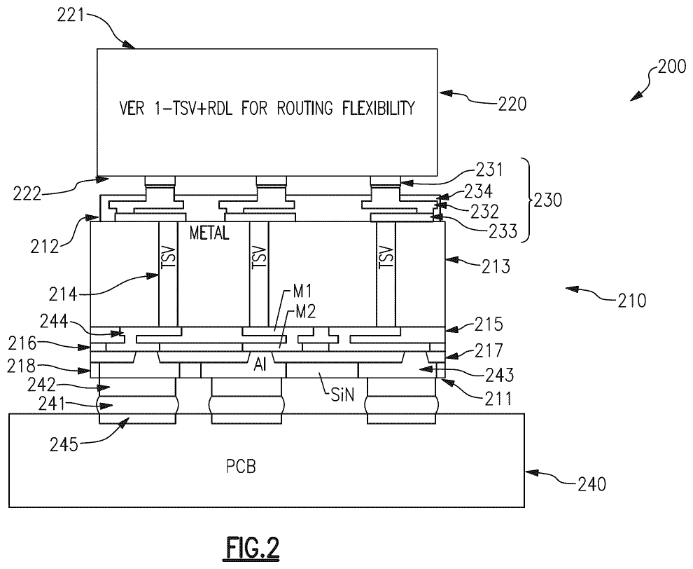

FIG. 2 shows a stacked die package 200 according to the present disclosure. The stacked die package 200 includes a first semiconductor die 210 and a second semiconductor die 220 bonded to each other. The first semiconductor die 210 includes a front side 211 (also called a front surface) and a back side 212 (also called a back surface) opposite to the front side. Similarly, the second semiconductor die 220 also includes a front side 221 and a back side 222 opposite to the front side. Throughout the present disclosure, the side of the semiconductor dies corresponding to the side of the semiconductor substrate having an active or functional device is referred to as the front side. The active or functional devices include but not limited to transistors, capacitors, resistors, diodes, photodiodes, fuse devices and/or other similar devices.

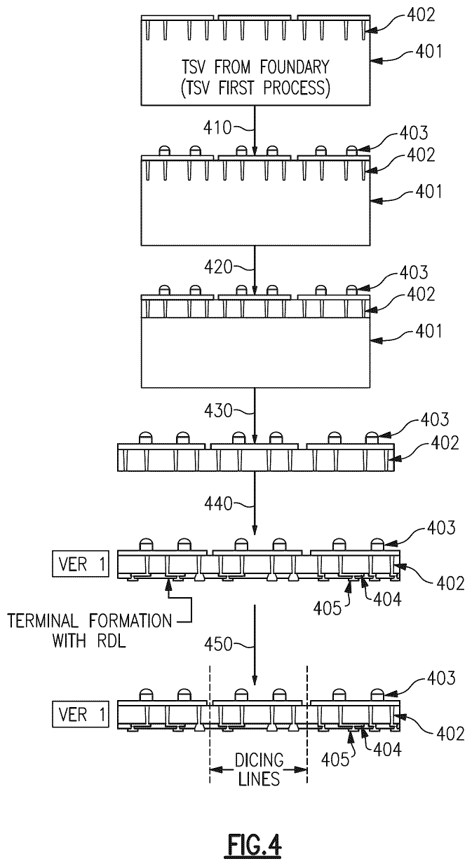

In some embodiments, the first die 210 is a die diced from a processed silicon wafer. Detailed processing steps are described in FIG. 4. The processed silicon wafer has a plurality of front end layers from a foundry and a plurality of TSVs. The first die 210, as a unit diced from the silicon wafer, includes a substrate 213, a first functional layer 215, a second functional layer 216, a third functional layer 217 and a top layer 218. The top layer 218 is a layer of silicon nitride. In some embodiments, the top layer 218 is a layer of organic passivation, such as polyimide. The first die 210 is in a flip-chip form wherein the front side 211 of the first die 210 is connected to a PCB pad 240.

As shown in FIG. 2, the first die 210 is connected to the PCB pad 240 through a plurality of interconnect components. The interconnect components include one or more micro copper pillars 242 with one or more corresponding tin/silver solder 241. One or more further metal pads 245 are used as landing pads for the first die 210 to locate the positions on the PCB substrate 24 and connect between the micro copper pillars 242 to the PCB substrate 240.

As shown in FIG. 2, the first die 210 and second die 220 are directly connected to each other in a front-to-back manner through a bonding structure 230 to form a die-to-die stack. This means that the front side 222 of the second die 220 is directly connected to the back side 212 of the first die 210, and the bonding structure 230 is formed between the back side 212 of the first die 210 and the front side 222 of the second die 220.

Such a die-to-die stack does not require any interposer in between. Therefore, the depth, or the size in the Y direction, is reduced. In addition, the first die 210 and second die 220 are connected in a vertical direction rather than in a side-to-side arrangement. Therefore, the width, or the size in the X direction, is also reduced. Such a die stack has good performance, in particular for low I/O count dies and provides wider applicability. Hence such a stacked die package can be considered to replace the die stack with an interposer in between.

To achieve a vertical die-to-die stack, TSVs are employed. The use of TSVs is a high-performance interconnect technique used as an alternative to wire-bond and flip chips to create three-dimensional (3D) packages. Advantageously, TSVs provide higher interconnect and device density and shorter lengths of connections.

As shown in FIG. 2, the first die 210 includes a plurality of TSVs 214 formed therein, such as from foundry. Each of the TSVs 214 vertically connects between the front side 211 and the back side 212 of the first die 210. In some embodiments, the TSVs 214 may include Cu, Ti, Ta, W, Ru, Co, Ni, the like, an alloy thereof, or a combination thereof.

In some embodiments, the front side 211 of the first die 210 includes a first active or functional electronic device, and the front side 222 of the second die 220 includes a second active or functional electronic device. The active or functional devices include but not limited to transistors, capacitors, resistors, diodes, photodiodes, fuse devices and/or other similar devices. Therefore, both the first die 210 and the second die 220 are active dies. Hence, through the front-to-back connection of the first die 210 and the second 220, the first active electronic device and the second electronic device are directly coupled to each other through the bonding structure and the TSVs 214 within the first die 210.

In detail, the bonding structure 230 between the first die 210 and the second die 220 includes one or more interconnect members. As shown in FIG. 2, the bonding structure of the stacked die package 200 includes one or more micro-pillars 231. Such micro-pillars 231 are normally used in interconnects for their high thermal conductivity, fine pitch, and resistance to electromigration. In some embodiments, the micro-pillars 231 are micro-copper-pillars having a fine pitch of down to 30μm in-line.

In some embodiments, the one or more interconnect members also include a redistribution layer (RDL) 232. The RDL 232 is an extra metalized layer that contains internal conducting paths for signal wiring and transmission paths. By adding one or more layers of lateral connections to the original substrate, the RDL helps maximize the signal interconnection density and overall flexibility of the product. The RDL may be aluminium (Al), copper (Cu) or a combination of aluminium and copper (AlCu). As shown in FIG. 2, at each of the micro-pillars 231 the RDL 232 is extended from the respective micro-pillar 231 to form a conducting path that directs to a desired location on the back side 212 of the first die 210. This means that the micro-pillars 231 can be flexibly directed to any location on the back side 212 of the first die 210 through the RDL 232 and hence to flexibly facilitate the connection between the first die 210 and the second die 220. The one or more interconnect members may also include one or more contact pads (or landing pads) 233 connected between the RDL 232 and the cross-sectional areas of the TSVs 214 at the back side 212 of the first die 210.

In some embodiments, the bonding structure also includes an encapsulant underfill 234.

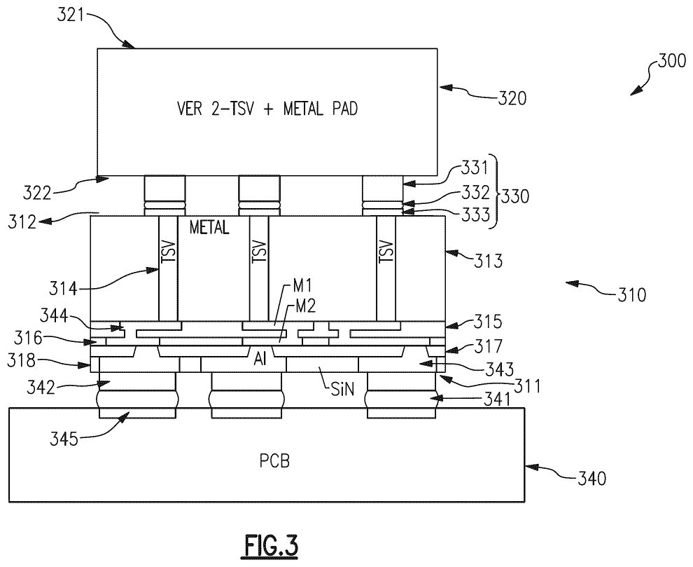

FIG. 3 shows another embodiment of a stacked die package 300 according to the present disclosure. Similar to the stacked die package 200 shown in FIG. 2, the stacked die package 300 includes a first semiconductor die 310 and a second semiconductor die 320 bonded to each other. The first semiconductor die 310 includes a front side 311 and a back side 312 opposite the front side. The second semiconductor die 320 also includes a front side 322 and a back side 321 opposite the front side 322. The front side 311 of the first die 310 includes a first active electronic device, and the front side 322 of the second die 320 includes a second active electronic device. Therefore, both the first die 310 and the second die 320 are active dies.

Similarly to the stacked die package 200 shown in FIG. 2, the first die 310 includes a plurality of TSVs 314 formed therein, such as from a foundry. Each of the TSVs 314 vertically connects between the front side 311 and the back side 312 of the first die 310.

The first die 310 and the second die 320 are connected to each other in a front-to-back manner through a bonding structure 330 connected to the plurality of TSVs to form a die-to-die stack. This means that the front side 322 of the second die 320 is connected to the back side 312 of the first die 310, and the bonding structure 330 is formed between the back side 312 of the first die 310 and the front side 322 of the second die 320. The first die 310 is in a flip-chip form wherein the front side 311 of the first die 310 is connected to a PCB pad 340.

Hence, through the front-to-back connection of the first die 310 and the second 320, the first active electronic device and the second electronic device are directly coupled to each other through the bonding structure and the TSVs 314 within the first die 310.

Similarly to the stacked die package 200 shown in FIG. 2, the first die 310 of the stacked die package 300 of FIG. 3 also includes a set of functional layers (layers 315 to 318).

The bonding structure 330 of the stacked die package 300 includes one or more interconnect members. The one or more interconnect members include one or more micro copper pillars 331 and one or more metal pads 332 patterned between the micro copper pillars 331 and the back side 312 of the first die 310. In some embodiments, the one or more interconnect members further include one or more contact pads (or landing pads) 333.

In some embodiments, the stacked die package is not limited to including a first and a second semiconductor dies. A multiple stacked dies assembly is formed in which a plurality of semiconductor dies are connected to each other in a back-to-front manner (e.g. similar to the connection between the first and second semiconductor dies shown in FIGS. 2 and 3). The plurality of semiconductor dies are formed in a vertical stack through a bonding structure between each two adjacent semiconductor dies in the vertical stack. Each semiconductor die includes a front side, a back side that is opposite to the front side, and one or more through substrate vias within the semiconductor die vertically connecting the front side and the back side and a back side that is opposite to the front side. The bonding structure between each two adjacent dies is configured to create a connection path between two adjacent semiconductor dies to the one or more through substrate vias of each semiconductor die of the plurality of semiconductor dies.

FIGS. 4 to 6 illustrate method steps in a process for manufacturing the stacked die package according to the present disclosure.

FIG. 4 shows a set of consecutive method steps 410 to 450 in a process for manufacturing the stacked die package 200 of FIG. 2. Initially, a silicon wafer 401 is provided from the foundry wherein a plurality of TSVs 402 are formed within the silicon wafer 401 near a surface of the silicon wafer 401. In a method step 410, the full thickness silicon wafer 401 is processed for bumping.

In some embodiments, micro copper pillars 403 are fabricated on the surface of the silicon wafer 401. Micro pillar bumping is a technology that uses copper pillars with micro-bumps to create vertical interconnects in electronic packaging. It replaces solder base bumps in flip chip interconnections, especially for devices that need a finer bump pitch.

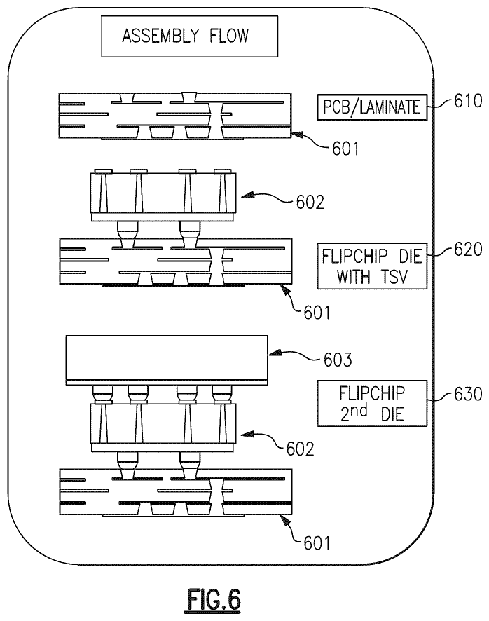

In the next method step 420, the silicon wafer 401 is processed by back-grinding and chemical mechanical polishing (CMP) at the back side. In a method step 430, the full-thickness silicon wafer 401 is eventually processed to reveal the embedded TSVs at the back side of the processed silicon wafer. Subsequently, method step 440 is a terminal formation step wherein the processed silicon wafer 401 including a plurality of TSVs 402 and a plurality of micro copper pillars 403 at the front surface is ready for a terminal formation. In the method step 440, the processed silicon wafer 401 is processed by adding a metal pad for making a RDL 404 as a form of terminal at the back of the silicon wafer 401. The terminal formation is then finished with a landing pad 405. Then, in a method step 450, the silicon wafer 401 is processed by dicing into smaller units (e.g. dies), as shown in FIG. 4. The dies are then assembled onto the corresponding PCBs in a set of subsequent method steps described in FIG. 6.

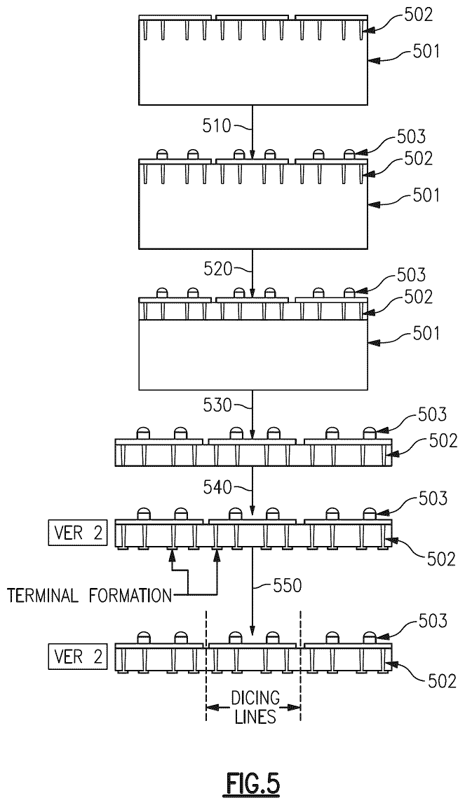

FIG. 5 shows another similar set of method steps 510 to 550 for manufacturing the stacked die package 300 of FIG. 3. Similar to FIG. 4, initially a full-thickness silicon wafer (e.g. from foundry) is provided, wherein a plurality of TSVs are formed. In a method step 510, the full-thickness silicon wafer is processed by copper pillar bumping. Next, method step 520 is a step for back-grinding and CMP at the back side of the silicon wafer and in a method step 530, the silicon wafer is processed to reveal the plurality of TSVs at the back side of the silicon wafer. Different to FIG. 4, in method step 540, the processed silicon wafer is then processed by directly adding a landing pad at each of the plurality of TSVs at the back side of the silicon wafer for terminal formation. There is no RDL formed. Then, in a method step 550, the processed silicon wafer is diced into dies for assembly onto corresponding PCBs in a set of subsequent method steps described in FIG. 6.

FIG. 6 shows a set of assembly steps 610 to 630 for any one of the dies diced from the processed silicon wafer shown in FIGS. 4 and 5. As an initial step 610, a PCB substrate 601 is provided on which the die is assembled. In a step 620, a first die 602 is added on to the PCB substrate 601. The first die 602 is a flip-chip die with a plurality of TSVs as described in FIGS. 4 and 5. The first die 602 is connected to the PCB substrate 601 through the micro copper pillars. In a step 630, a second die 603 is directly added at the back side of the first die 602. The second die 603 is also a flip-chip die. The second die 603 includes a front side having a plurality of micro copper pillars. The front side of the second die 603 is therefore connected to the back side of the first die 602 through the plurality of micro copper pillars wherein each micro copper pillar is in contact with a landing pad at the back of the first die 602.

Having described above several aspects of at least one embodiment, it is to be appreciated various alterations, modifications, and improvements will readily occur to those skilled in the art. Such alterations, modifications, and improvements are intended to be part of this disclosure and are intended to be within the scope of the invention. Accordingly, the foregoing description and drawings are by way of example only, and the scope of the invention should be determined from proper construction of the appended claims, and their equivalents.

What is claimed is:

1. A stacked die package comprising:
a first semiconductor die including a front side, a back side that is opposite to the front side, and one or more through substrate vias within the first semiconductor die vertically connecting the front side and the back side of the first semiconductor die;
a second semiconductor die including a front side and a back side that is opposite to the front side; and
a bonding structure between the back side of the first semiconductor die and the front side of the second semiconductor die and configured to create a connection path from the front side of the second semiconductor die to the one or more through substrate vias of the first semiconductor die at the back side of the first semiconductor die.

2. The stacked die package of claim 1 wherein the front side of the first semiconductor die includes a first active electronic device and the front side of the second semiconductor die includes a second active electronic device.

3. The stacked die package of claim 2 wherein the bonding structure is configured to couple the first active electronic device of the first semiconductor die and the second active electronic device of the second semiconductor die.

4. The stacked die package of claim 1 wherein the bonding structure includes one or more interconnect members connected to the one or more through substrate vias.

5. The stacked die package of claim 4 wherein the one or more interconnect members include micro copper pillars.

6. The stacked die package of claim 5 wherein the one or more interconnect members include a redistribution layer coupled to the micro copper pillars.

7. The stacked die package of claim 6 wherein the one or more interconnect members include landing pads each connected between the redistribution layer and the one or more through substrate vias.

8. The stacked die package of claim 1 wherein the front side of the first semiconductor die is connected to a printed circuit board through one or more bonding elements.

9. The stacked die package of claim 8 wherein the one or more bonding elements include a plurality of micro copper pillars.

10. The stacked die package of claim 9 wherein the one or more bonding elements further include metal pads configured to connect the plurality of micro copper pillars to the printed circuit board.

11. The stacked die package of claim 1 wherein one or both of first semiconductor die and the second semiconductor die are flip-chip dies.

12. A multiple stacked dies assembly comprising:
a plurality of semiconductor dies connected to each other back-to-front in a vertical stack through a bonding structure between each two adjacent semiconductor dies, wherein each semiconductor die of the plurality of semiconductor dies includes: a front side, a back side that is opposite to the front side, and one or more through substrate vias within the semiconductor die vertically connecting the front side and the back side and a back side that is opposite to the front side; and wherein the bonding structure is configured to create a connection path between two adjacent semiconductor dies to the one or more through substrate vias of each semiconductor die of the plurality of semiconductor dies.

13. A method of manufacturing a stacked die package, the method comprising:
forming copper pillar bumps on a silicon wafer, the silicon wafer including a front side, a back side that is opposite to the front side, and one or more through substrate vias within the silicon wafer vertically connecting the front side and the back side of the silicon wafer;
grinding and polishing the back side of the silicon wafer to reveal the one or more through substrate vias at the back side;
fabricating one or more connection components at the back side of the silicon wafer;
dicing the silicon wafer to divide into a plurality of first semiconductor dies, each first semiconductor die including a front side, a back side that is opposite to the front side, and one or more through substrate vias within the first semiconductor die; and
coupling a second semiconductor die to the first semiconductor die through connecting one or more micro copper pillars on a front side of the second semiconductor die to the one or more connection components at the back side of the first semiconductor die.

14. The method of claim 13 wherein the one or more connection components include a redistribution layer.

15. The method of claim 13 wherein the one or more connection components include one or more landing pads.

16. The method of claim 14 wherein the front side of the first semiconductor die includes a first active electronic device and the front side of the second semiconductor die includes a second active electronic device.

17. The method of claim 14 further comprising coupling the front side of the second semiconductor die to the back side of the first semiconductor die through the redistribution layer.

18. The method of claim 14 wherein the one or more connection components further include one or more landing pads, and the redistribution layer is connected between the one or more micro copper pillars on the front side of the second semiconductor die and the landing pads.

19. The method of claim 15 further comprising directly coupling the front side of the second semiconductor die to the back side of the first semiconductor die at the one or more landing pads.

20. The method of claim 13 further comprising connecting the first semiconductor die to a printed circuit board through one or more copper pillars at the front side of the first semiconductor die.

21. The method of claim 15 wherein the first semiconductor die and the second semiconductor die are both flip-chip dies.
